(19) United States
(12) Patent Application Publication
(10) Pub. No.: US 2021/0191006 A1
(43) Pub. Date: Jun. 24, 2021

(54) DISPLAY DEVICE

(71) Applicant: SONY CORPORATION, TOKYO (JP)

(72) Inventors: MAMORU SUZUKI, KANAGAWA (JP); KOTARO SHIMA, KANAGAWA (JP); SHUTARO KUROKAWA, KANAGAWA (JP)

(21) Appl. No.: 16/758,036

(22) PCT Filed: Oct. 3, 2018
(86) PCT No.: PCT/JP2018/037001

§ 371 Date: Apr. 21, 2020

(30) Foreign Application Priority Data
Oct. 31, 2017 (JP) 2017-210506

(51) Int. Cl. G02B 5/02

(52) U.S. Cl. CPC G02B 5/0294; G02F 1/133553; G02B 5/0221

(57) ABSTRACT

A display device includes a plurality of arrayed light output sections 21 covered with a laminated structure 30; the laminated structure 30 includes a plurality of laminated layers, a light output surface 30A is flat, and plural recessed and projected sections 52 are formed on an interface of at least one layer (recessed and projected section forming layer 51) positioned in the laminated structure 30.

### TECHNICAL FIELD

The present disclosure relates to a display device.

### BACKGROUND ART

Light emitting diode display devices each including light emitting elements, specifically, light emitting diodes (LEDs), arrayed in the form of a two-dimensional matrix have been well known. In order to obtain high contrast, therein, a structure having the LEDs covered with a protective layer, having a layer (black matrix layer) including a light impermeable material formed on the protective layer, and having an antireflection membrane formed on the black matrix layer is often adopted. The light emitting diode display devices having such a structure, however, still have a problem in that reflection of an environment in a vicinity of a surface of the light emitting diode display device may occur on the surface of the light emitting diode display device, under strong ambient light, so that the environment may be viewed on the surface of the light emitting diode display device, for instance. Incidentally, such a phenomenon is referred to as “reflection” for convenience, sharpness of an image viewed through the reflection is expressed as “image clarity,” high “image clarity of reflection” means that the image has high sharpness, and low “image clarity of reflection” means that the image has low sharpness.

A mechanism for settling such a problem, that is, a mechanism for lowering the image clarity of reflection, is disclosed in Japanese Patent Laid-open No. 2015-034948, for instance. Specifically, a display device disclosed in Japanese Patent Laid-open No. 2015-034948 has a structure which includes

plural light emitting sections,

a light absorbing section that surrounds each of the plural light emitting sections, and

low-reflection layers that are provided on surfaces of both the light emitting sections and the light absorbing section, in which

the surface of the light absorbing section is a recessed and projected surface that diffuses light, and

the low-reflection layer is provided so as to conform to the recessed and projected surface.

### CITATION LIST

### Patent Literature

### [PTL 1]

Japanese Patent Laid-open No. 2015-034948

### SUMMARY

### Technical Problem

According to a technique disclosed in this PTL, the image clarity of reflection may be reduced. The low-reflection layer positioned on an outmost surface of the display device, however, is recessed and projected, and thus, the lowering of the outside light contrast is prone to be caused by scattering of the light from the light emitting sections by the low-reflection layer. It is desirable for an observed surface of the light emitting diode display device to be seen in a black sunken state, from a viewpoint of improvement in image quality or the like. In a case where the outside light contrast is lowered, however, the surface may not be seen in the black sunken state. In other words, what is generally called a misadjusted black level may occur.

Therefore, an object of the present disclosure is to provide a display device by which the image clarity of reflection may be lowered and which further has a configuration and a structure that are less likely to lower the outside light contrast.

### Solution to Problem

A display device of the present disclosure to achieve the abovementioned object is a display device including a plurality of arrayed light output sections covered with a laminated structure, in which the laminated structure includes a plurality of laminated layers, and a light output surface is flat, and plural recessed and projected sections are formed on an interface of at least one layer positioned in the laminated structure.

### BRIEF DESCRIPTION OF DRAWINGS

FIG. 1A and FIG. 1B are, respectively, a schematic fragmentary sectional view of a display device of embodiment 1 and a schematic fragmentary sectional view of the display device for description of a principle by which image clarity of reflection may be lowered in the display device of embodiment 1.

FIG. 2A and FIG. 2B are a schematic plan view of plural recessed and projected sections in the display device of embodiment 1 and a schematic perspective view of one of the recessed and projected sections.

FIG. 3A and FIG. 3B are a schematic plan view and a schematic perspective view of modification −1 of the plural recessed and projected sections in the display device of embodiment 1.

FIG. 4 is a schematic plan view of modification −2 of the plural recessed and projected sections in the display device of embodiment 1.

FIG. 5 is a schematic plan view of modification −3 of the plural recessed and projected sections in the display device of embodiment 1.

FIG. 6 is a schematic plan view of modification −4 of the plural recessed and projected sections in the display device of embodiment 1.

FIG. 7 is a layout drawing schematically illustrating placement of the recessed and projected sections in modification −1 of the plural recessed and projected sections in the display device of embodiment 1.

FIG. 8 is a layout drawing schematically illustrating a modification to the placement of the recessed and projected sections in modification −1 of the plural recessed and projected sections in the display device of embodiment 1.

FIG. 9 is a layout drawing schematically illustrating another modification to the placement of the recessed and projected sections in modification −1 of the plural recessed and projected sections in the display device of embodiment 1.

FIG. 10 is a diagram illustrating a system in which a simulation for evaluation of the image clarity of reflection and outside light contrast is conducted in embodiment 1.

FIG. 11 illustrates in (A-1) and (B-1) images obtained from light reflected by light output surfaces of laminated structures on the basis of the simulation, in a conventional display device and the display device of embodiment 1. FIG. 11 illustrates in (A-2) and (B-2) images obtained from light reflected by black matrix layers and recessed and projected section forming layers of the display devices on the basis of the simulation, in the conventional display device and the display device of embodiment 1. FIG. 11 depicts in (A-3) and (B-3) an image resulting from composition of the image illustrated in (A-1) and the image illustrated in (A-2) and an image resulting from composition of the image illustrated in (B-1) and the image illustrated in (B-2). FIG. 11 illustrates in (C-1) a result of a simulation as to how an image of a grid light source is viewed in the conventional display device. FIG. 11 depicts in (C-2) and (C-3) results of a simulation as to how the image of the grid light source is viewed in the display device of embodiment 1 in which a maximum inclination α is set at one degree and at two degrees.

FIG. 12 depicts in (A) and (B), respectively, schematic perspective views of the recessed and projected section forming layers in the display device of embodiment 1 and modification −1 thereto and diagrams illustrating results of measurement of luminance of images of the grid light source and images of regions positioned outside and in vicinities of the images of the grid light source.

FIG. 13 presents a schematic perspective view of the black matrix layer in the conventional display device having a surface of the black matrix layer randomly roughened by sandblasting and a diagram illustrating a result of measurement of luminance of an image of the grid light source and that of an image of a region positioned outside and in a vicinity of the image of the grid light source.

FIG. 14A is a graph illustrating shapes of cross-sections of slopes of the recessed and projected section that are linear and curved in the display device of embodiment 1, FIG. 14B presents diagrams illustrating results of the evaluation of the image clarity of reflection in these cases based on the simulation, and FIG. 14C presents diagrams schematically illustrating behavior of light reflected by the slopes of the recessed and projected sections that are linear and curved in the display device of embodiment 1.

FIG. 15 is a graph illustrating heights of slopes and inclination angles of the slopes in a case where cross-sections of the slopes cut by virtual planes including axes of the recessed and projected sections are curved in the display device of embodiment 1.

FIG. 16 depicts in (A) and (B) diagrams illustrating results of a simulation as to how much the image clarity of reflection is changed according to presence or absence of an antireflection membrane. FIG. 16 depicts in (C) and (D) diagrams illustrating results of a simulation as to how much the image clarity of reflection is changed in the display device of embodiment 1 between a case where each of the plural recessed and projected sections is placed on a vertex of a rectangle and a placement pitch thereof is 50 μm and a case where each of the plural recessed and projected sections is placed on a vertex of a rectangle and the placement pitch is 100 μm.

FIG. 17 depicts in (A), (B), (C), and (D) diagrams illustrating part of results of simulations of the image clarity of reflection on the recessed and projected section forming layers having various planar shapes.

FIG. 18 presents diagrams illustrating overall results of simulations of the image clarity of reflection in modification −1 and modification −2 to the display device of embodiment 1 and in the display device of embodiment 1.

FIG. 19 depicts in (A), (B), and (C) diagrams illustrating part of results of simulations of the image clarity of reflection in the display device of embodiment 1 in a case where the plural recessed and projected sections are placed on vertices of a rectangle, in a case where the plural recessed and projected sections are placed on vertices of a hexagon, and in a case where the plural recessed and projected sections are placed radially.

FIG. 20 is a graph illustrating results of calculation of relationships between a maximum inclination (α) and Δθ{=θ₂ᵢ−θ₁ᵣ] in the display device of embodiment 1 in a case of n₁=1.50.

FIG. 21 is a schematic fragmentary sectional view of a conventional display device for description of problems of the conventional display device.

FIG. 22A and FIG. 22B are schematic fragmentary sectional views of display devices, illustrating behavior of incident light and output light based on outside light in the display device of embodiment 1 and a conventional display device, and FIG. 22C is a schematic fragmentary sectional view illustrating details of the behavior of the incident light and the output light based on the outside light in the display device of embodiment 1.

FIG. 23 is a schematic fragmentary sectional view of a display device including an electroluminescence display device (organic EL display device).

FIG. 24 is a schematic fragmentary sectional view of a display device including a liquid crystal display device.

FIG. 25A and FIG. 25B are exterior diagrams respectively illustrating examples of a television receiver and a notebook personal computer, as the display device.

### DESCRIPTION OF EMBODIMENT

The present disclosure will be described below on the basis of an embodiment with reference to the drawings but is not limited to the embodiment. Various numerical values, materials, and the like in the embodiment are presented as examples. Further, description will be given in the following order.

1. Display device of present disclosure, general description

2. Embodiment 1 (display device of present disclosure)

3. Others

### Display Device of Present Disclosure, General Description

In the description below, a layer having plural recessed and projected sections formed on an interface will be referred to as a “recessed and projected section forming layer” for convenience.

In a display device of the present disclosure, a laminated structure may have a form which includes a light passing region through which light outputted from each of light output sections passes and a light non-passing region which is positioned outside the light passing region and which blocks passage of the light outputted from the light output section; at least one layer (recessed and projected section forming layer) positioned in the laminated structure is positioned in the light non-passing region, and a recessed and projected section is formed on an interface on a light output side of the at least one layer (recessed and projected section forming layer) positioned in the laminated structure. In this case, additionally, the layer (recessed and projected section forming layer) on which the plural recessed and projected sections are formed may have a form including a material that blocks passage of light. Here, as an example of the material that blocks the passage of light, a material having powdered carbon, for instance, added to acrylic resin, epoxy-based resin, urethane-based resin, silicone-based resin, or cyanoacrylate-based resin may be presented. Further, as a method of forming such a recessed and projected section forming layer, a method suitable for these materials, such as application method or printing method, may be presented. As an example of a method of forming the recessed and projected sections, a stamp method with use of a stamper, a resist etchback method, or the like may be presented. It is to be noted that in a case where the light non-passing region has a small thickness, a slight portion of the light outputted from the light output sections may pass through the light non-passing region. Even in such a case, however, it is to be deemed that “the light non-passing region blocks the passage of the light outputted from the light output sections.”

In the display device of the present disclosure including the above preferred forms, it is desirable to satisfy 0<α≤θ_{c}/2 in which θ_{c} is a critical angle to air of a material constituting a layer (which may be referred to as an “adjacent layer” for convenience) that adjoins, on the light output side, the layer (recessed and projected section forming layer) on which the plural recessed and projected sections are formed and in which a is a maximum inclination of a slope of each of the recessed and projected sections and, specifically, a value between one degree and two degrees may be presented as a value of a, though there is no limitation thereto. In this case, furthermore, it is desirable for a cross-section (which may simply be referred to as a “cross-section of slope” below) of the slope cut by a virtual plane including an axis of each of the recessed and projected sections to include a curve. As the curve, for instance, a combination (such as a shape approximate or similar to bell shape, spindle shape, or the like) of a smooth curve that is projected downward, an inflection point, and a smooth curve that is projected upward, extending from a lower end of the slope to an upper end of the slope, may be presented. Meanwhile, minute recesses and projections may appear on the slope, depending on a method of forming the slope, when the slope is observed in detail, whereas it may be said that a cross-section of the slope includes a curve if the slope is smooth when being observed macroscopically. Additionally, it is desirable for a cross-sectional shape of a top face of the recessed and projected section to include a smooth curve that is projected upward, though there is no limitation thereto. Similarly, minute recesses and projections may appear on the light output surface, depending on a method of forming the light output surface, when the flat light output surface is observed in detail, whereas it may be said that the light output surface is flat if the light output surface is smooth when being observed macroscopically.

Furthermore, in the display devices of the present disclosure including the various desirable forms described above, a form in which an antireflection membrane is formed on the light output surface of the laminated structure may be included. The antireflection membrane may be formed on the light output surface of the laminated structure by, for instance, inclusion of an antireflection film (AR film) in the antireflection membrane and pasting of the antireflection film (AR film) onto the light output surface. Alternatively, the antireflection membrane including dielectric multilayer including a material with a low refractive index and a material with a high refractive index may be formed on the light output surface of the laminated structure by physical vapor deposition method (PVD method) such as various schemes of application method, sputtering method, or the like.

In the display devices of the present disclosure including the various desirable forms described above, furthermore, a planar shape of each of the recessed and projected sections may have a form including at least one type of shape selected from a group including a plurality of concentric circles, a plurality of concentric rectangles, a plurality of concentric polygons, a set of a plurality of line segments extending radially, a plurality of dots regularly arrayed, and a set of line segments that are line-asymmetric, point-asymmetric, and rotationally asymmetric (set of randomly placed line segments) or may be any combination of these shapes. Positional relationships between each of the plural recessed and projected sections and the light output sections are essentially optional.

In the display devices of the present disclosure including the various desirable forms described above, furthermore, each of the plural recessed and projected sections may have a form of being placed on a vertex of a rectangle, on a vertex of a hexagon, or radially or randomly placed or may have any combination of these placements. Meanwhile, the plural recessed and projected sections may be placed line-symmetrically, point-symmetrically, rotationally symmetrically, or asymmetrically. Relationship between a placement position of each of the plural recessed and projected sections and placement positions of the light output sections are essentially optional.

In the display devices of the present disclosure including the various desirable forms described above, furthermore, a form in which outside light incident from the light output surface of the laminated structure, except a portion absorbed by the laminated structure or the recessed and projected section forming layer, is reflected by the layer on which the plural recessed and projected sections are formed and is outputted from the light output surface of the laminated structure may be included.

In the display devices of the present disclosure including the various desirable forms described above, furthermore, a configuration in which the light output sections include light emitting diodes (LEDs) or semiconductor laser elements may be included. It is to be noted that in these configurations, a configuration in which the light output sections including light emitting elements including light emitting diodes or semiconductor laser elements are fixed (mounted) onto a base may be included. Specifically, a configuration in which the light output sections are fixed (mounted) onto a wiring layer formed on the base including a glass substrate, a printed wiring board, or the like, for instance, may be included.

In the display devices of the present disclosure including the various desirable forms described above, meanwhile, the light output sections may have a configuration including electroluminescence elements (EL elements) or including liquid crystal display elements. In these configurations, meanwhile, the laminated structure may have a configuration including the light passing region through which light outputted from each of the light output sections passes and the light non-passing region which is positioned outside the light passing region and which blocks the passage of the light outputted from the light output sections or the laminated structure may have a structure in which layers including a material transparent to the light outputted from the light output sections are laminated, as a whole. In the latter case, the layer (recessed and projected section forming layer) on which the plural recessed and projected sections are formed does not have to include a material that blocks passage of light. Here, in the configuration in which the light output sections include electroluminescence elements (EL elements) or liquid crystal display elements, the display device may include an electroluminescence display device or a liquid crystal display device.

In a case where the light output sections include light emitting diodes, semiconductor laser elements, or the like in the display devices of the present disclosure including the various desirable forms or configurations described above (which may collectively be referred to as “the display devices of the present disclosure and the like” below), a size of the light output sections (such as a chip size) is not particularly limited but, typically, is minute, specifically, equal to or smaller than 1 mm, for instance, or equal to or smaller than 0.3 mm, for instance, or equal to or smaller than 0.1 mm, for instance, or more specifically, equal to or smaller than 0.03 mm. The number, a type, mounting (placement), an interval, or the like of the light output sections that constitute the display devices and the like is determined according to an application or a function of the display devices and the like, specifications demanded for the display devices and the like, or the like. The light output sections may include red light output sections that emit red light, green light output sections that emit green light, or blue light output sections that emit blue light, or may include a combination of the red light output sections, the green light output sections, and the blue light output sections. That is, the light output sections may include a package of the red light output sections, a package of the green light output sections, a package of the blue light output sections, or a package of light emitting units including the red light output sections, the green light output sections, and the blue light output sections. As a material constituting the package, ceramic, resin, metal, and the like may be presented, and a structure in which wiring is provided on a substrate constituting the package may be presented.

The plural light output sections (plural pixels) are arrayed in the form of a two-dimensional matrix in a first direction and a second direction orthogonal to the first direction, for instance. With the number of the red light output sections constituting the light emitting units set as N_{R}, the number of the green light output sections constituting the light emitting units set as N_{G}, and the number of the blue light output sections constituting the light emitting units set as N_{B}, one or an integer of two or larger may be presented as N_{R}, one or an integer of two or larger may be presented as N_{G}, and one or an integer of two or larger may be presented as N_{B}. Values of N_{R}, N_{G}, and N_{B} may be equal or may be different. In a case where the values of N_{R}, N_{G}, and N_{B} are integers of two or larger, the light output sections may be connected in series or in parallel in one light emitting unit. As a combination of the values of (N_{R}, N_{G}, N_{B}), (1, 1, 1), (1, 2, 1), (2, 2, 2), and (2, 4, 2) may be presented as examples, though there is no limitation thereto. In a case where one pixel includes three types of sub pixels, delta array, stripe array, diagonal array, and rectangle array may be presented as an array of the three types of sub pixels. In a case where the light output sections include light emitting elements, further, it is sufficient if the light emitting elements are driven based on PWM drive method and with a constant current. Meanwhile, three panels may be prepared, a first panel may include a plurality of light emitting elements including the red light output sections, a second panel may include a plurality of light emitting elements including the green light output sections, and a third panel may include a plurality of light emitting elements including the blue light output sections, and application such panels to a projector in which light from the three panels is collected with use of a dichroic prism, for instance, may be achieved.

In a case where the light output sections include light emitting elements, III-V compound semiconductor may be presented as a material constituting light emitting layers of the red light output sections, the green light output sections, and the blue light output sections (or the green light output sections and the blue light output sections), for instance, and AlGaInP-based compound semiconductor may be presented as a material constituting light emitting layers of the red light output sections, for instance. As examples of the III-V compound semiconductor, GaN-based compound semiconductor (including AlGaN mixed crystal, AlGaInN mixed crystal, or GaInN mixed crystal), GaInNAs-based compound semiconductor (including GaInAs mixed crystal or GaNAs mixed crystal), AlGaInP-based compound semiconductor, AlAs-based compound semiconductor, AlGaInAs-based compound semiconductor, AlGaAs-based compound semiconductor, GaInAs-based compound semiconductor, GaInAsP-based compound semiconductor, GaInP-based compound semiconductor, GaP-based compound semiconductor, InP-based compound semiconductor, InN-based compound semiconductor, and AlN-based compound semiconductor may be presented, for instance.

As a material constituting the layer (adjacent layer) that adjoins, on the light output side, the layer (recessed and projected section forming layer) on which the plural recessed and projected sections are formed, in the laminated structure, acrylic resin, silicone-based resin, or urethane-based resin may be presented or the material may include a material referred to as OCA (Optical Clear Adhesive). Further, the laminated structure may have a form in which a second protective layer including a polyethylene terephthalate film (PET film), a cycloolefin copolymer film (COC film), or the like is laminated on the adjacent layer, for instance, in which a surface of the second protective layer constitutes the light output surface, and in which an antireflection membrane is formed on the surface of the second protective layer.

Meanwhile, the laminated structure may have a form in which a resin layer (protective layer) that is transparent to the light outputted from the light output sections and that is highly insulative is formed between the layer (recessed and projected section forming layer) on which the plurality of recessed are formed and the light output sections. As examples of a material that constitutes the resin layer, acrylic resin, epoxy-based resin, urethane-based resin, silicone-based resin, and cyanoacrylate-based resin may be presented.

### Embodiment 1

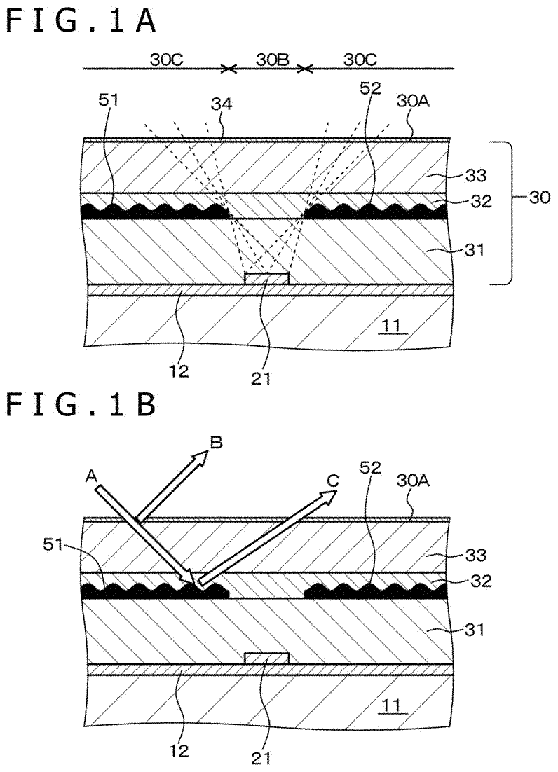

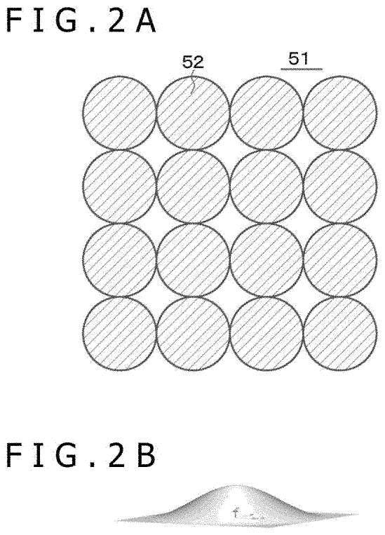

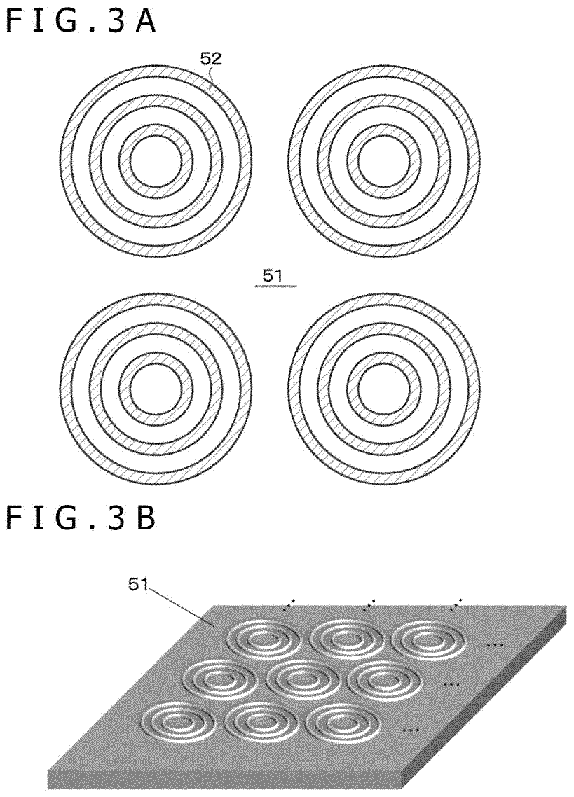

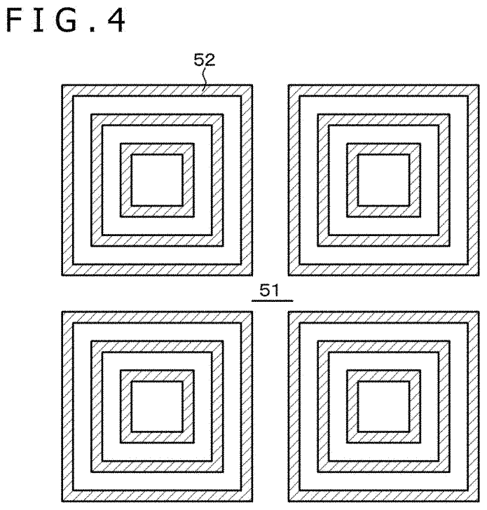

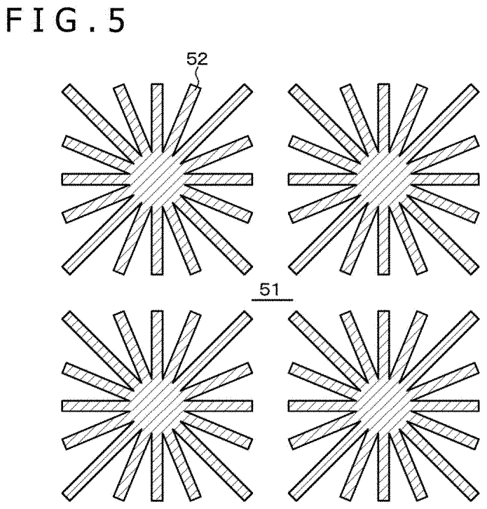

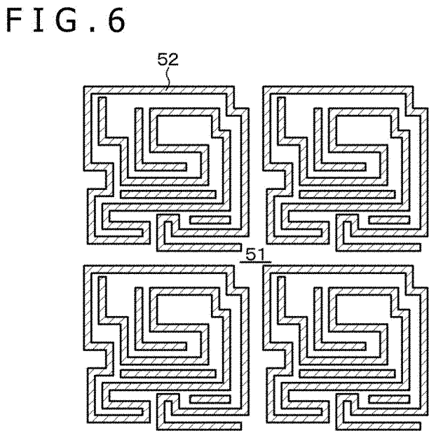

Embodiment 1 relates to the display device of the present disclosure. FIG. 1A illustrates a schematic fragmentary sectional view of the display device of embodiment 1, and FIG. 1B illustrates a schematic fragmentary sectional view of the display device for description of a principle by which the image clarity of reflection may be lowered in the display device of embodiment 1. Further, FIG. 2A illustrates a schematic plan view of the plural recessed and projected sections in the display device of embodiment 1, and FIG. 2B illustrates a schematic perspective view of one of the recessed and projected sections. In FIG. 2A and FIG. 3A, FIG. 4, FIG. 5, and FIG. 6 that will be described later, incidentally, the recessed and projected section forming layer is shaded to clearly indicate the recessed and projected section forming layer.

The display device of embodiment 1 includes a plurality of arrayed light output sections 21 covered with a laminated structure 30. Additionally, the laminated structure 30 includes a plurality of laminated layers, a light output surface 30A is flat, and plural recessed and projected sections 52 are formed on an interface of at least one layer (recessed and projected section forming layer 51) positioned in the laminated structure 30.

In the display device of embodiment 1, the laminated structure 30 includes a light passing region 30B through which light outputted from each of the light output sections 21 passes and a light non-passing region 30C which is positioned outside the light passing region 30B and which blocks passage of the light outputted from the light output sections 21, the at least one layer (recessed and projected section forming layer 51) positioned in the laminated structure 30 is positioned in the light non-passing region 30C, and the recessed and projected section 52 are formed on an interface on a light output side of the at least one layer (recessed and projected section forming layer 51) positioned in the laminated structure 30. Here, the layer (recessed and projected section forming layer 51) on which the plural recessed and projected sections 52 are formed includes a material that blocks passage of light. Specifically, for instance, the layer includes a material having powdered carbon added to acrylic resin and is formed by application method, printing method, or the like, and the recessed and projected sections 52 may be formed by stamp method with use of a stamper, resist etch-back method, or the like.

In the display device of embodiment 1, additionally, an antireflection membrane 34 is formed on the light output surface 30A of the laminated structure 30. The antireflection membrane 34 includes an antireflection film (AR film), for instance, and the antireflection membrane 34 may be formed on the light output surface 30A of the laminated structure 30 by pasting of the antireflection film (AR film) onto the light output surface 30A of the laminated structure 30.

In the display device of embodiment 1, planar shapes of the recessed and projected sections 52 form plural dots regularly arrayed, and each of the plural recessed and projected sections 52 is placed on a vertex of a rectangle. Positional relationships between each of the plural recessed and projected sections 52 and the light output sections 21 are essentially optional, and relationships between a placement position of each of the plural recessed and projected sections 52 and placement positions of the light output sections 21 is essentially optional as well. That is, in an example illustrated in FIG. 2A, for instance, while the recessed and projected sections 52 numbered 4×4=16 are illustrated and the recessed and projected section forming layer 51 is observed between recessed and projected sections 52, it is sufficient if the light output section 21 is formed anywhere in a region illustrated in this FIG. 2A or the light output section 21 may be formed outside the region illustrated in this FIG. 2A, for instance. As described before, further, it is sufficient if the laminated structure 30 includes the light passing region 30B through which the light outputted from each of the light output sections 21 passes and the light non-passing region 30C which is positioned outside the light passing region 30B and which blocks the passage of the light outputted from the light output sections 21. A cross section of a slope cut by a virtual plane including an axis of the recessed and projected section 52 makes a curve as seen in FIG. 2B.

In the display device of embodiment 1, additionally, the light output sections 21 include light emitting diodes (LEDs), and the light output sections 21 are fixed (mounted) onto a base. Specifically, the light output sections 21 are fixed onto a wiring layer 12 formed on the base 11 including a glass substrate, a printed wiring board, or the like, for instance. The light output sections 21 may include a package of light emitting units including red light output sections that emit red light, green light output sections that emit green light, and blue light output sections that emit blue light. The red light output sections, the green light output sections, and the blue light output sections have a configuration and a structure that are well known, and the package also has a configuration and a structure that are well known. In a case where the light output sections 21 include the light emitting units, additionally, one pixel that constitutes the display device includes one red light output section, one green light output section, and one blue light output section, as described above, for instance. That is, N_{R}=N_{G}=N_{B}=1 holds.

In the laminated structure 30, a resin layer (protective layer) 31 including acrylic resin, the recessed and projected section forming layer 51, an adjacent layer 32 including OCA including acrylic resin, and a second protective layer 33 including a PET film are laminated from a side of the base. In manufacturing the display device, laminate material in which the second protective layer 33 having the antireflection membrane 34 formed on the light output surface 30A and the adjacent layer 32 are laminated is prepared. On the other hand, the resin layer 31 may be obtained by application of resin that constitutes the resin layer 31 onto the light output sections 21 mounted on the wiring layer 12 formed on the base 11, the wiring layer 12, and the base 11 and by curing of the resin, and thereafter, the recessed and projected section forming layer 51 may be obtained by application, exposure, and curing of resin that constitutes the recessed and projected section forming layer 51 on the resin layer 31, by formation of the light passing region 30B and the light non-passing region 30C, and further by forming of the recessed and projected sections 52. After that, the laminate material is pasted on the recessed and projected section forming layer 51 (light passing region 30B) and the light non-passing region 30C. Meanwhile, the adjacent layer 32 of a thermoplastic and ultraviolet curable type may be used. In a case where a material that constitutes the adjacent layer 32 is liquid, otherwise, the liquid material may be applied onto the recessed and projected section forming layer 51 (light passing region 30B) and the light non-passing region 30C and may be precured, as appropriate, and thereafter, the adjacent layer 32 and the second protective layer 33 that is superposed thereon may be integrated by curing of the liquid material by ultraviolet.

FIG. 21 illustrates a schematic fragmentary sectional view of a conventional display device for description of problems of the conventional display device, and a portion of outside light A incident on the display device is specularly reflected, for instance, by the light output surface 30A of the laminated structure 30 as illustrated in FIG. 1B and FIG. 21. Incidentally, a specularly reflected light ray is denoted by “B” in FIG. 1B and FIG. 21. A remaining portion (excluding a portion absorbed by a region of the light output surface and the like) of the outside light A incident on the display device intrudes into the laminated structure 30. Then, the remaining portion collides with the recessed and projected section forming layer 51 and is thereby reflected as illustrated in FIG. 1B. The reflected light ray is denoted by “C” in FIG. 1B. In the conventional display device illustrated in FIG. 21, by contrast, the portion of the light collides with what is generally called a black matrix layer 51″ on which no recessed and projected sections are formed and is thereby reflected. The reflected light ray is denoted by “C″” in FIG. 21. In the conventional display device, the light ray B and the light ray C″ are parallel because of collision with and reflection on the flat black matrix layer 51″. In the display device of embodiment 1, by contrast, the light ray B and the light ray C are nonparallel because of collision with and reflection on the recessed and projected section forming layer 51.

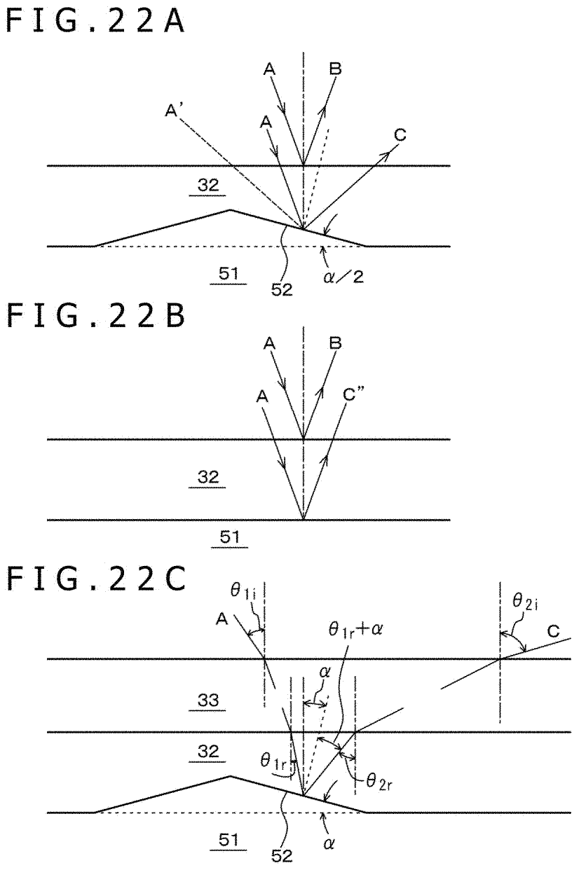

For simplification of description, it is assumed that the recessed and projected sections 52 include square pyramids having a maximum inclination of a (degrees). Here, FIG. 22A illustrates a schematic fragmentary sectional view of the display device that includes the recessed and projected section 52 including the square pyramid and that is cut by a virtual plane including a vertex of the square pyramid and a region of a slope having the maximum inclination of a (degrees). In addition, FIG. 22B illustrates a schematic fragmentary sectional view of the conventional display device. That is, FIG. 22A and FIG. 22B illustrate the schematic fragmentary sectional views of the display devices, illustrating behavior of incident light and output light in the display device of embodiment 1 and the conventional display device. In FIG. 22A, FIG. 22B, and FIG. 22C that are the fragmentary sectional views, meanwhile, shading is omitted.

In the conventional display device, as illustrated in FIG. 22B, the light ray B and the light ray C″ are parallel because of the collision with and the reflection on the flat black matrix layer 51″. By contrast, in the display device of embodiment 1, as illustrated in FIG. 22A, the light ray B and the light ray C are nonparallel because of the collision with and the reflection on the recessed and projected section forming layer 51. An image formed on the basis of the light ray C is observed as if the image was formed on the basis of a light ray A′. That is, in the display device of embodiment 1, an image formed on the basis of the light ray B is observed as if formed on the basis of the light ray A, the image formed on the basis of the light ray C is observed as if formed on the basis of the light ray A′, and thus, objects (real object and virtual object) on which the images are based are viewed as if positioned in different places. Therefore, definiteness and clarity of an image reflected on the light output surface 30A are lowered so that image clarity of reflection may be reduced.

FIG. 22C illustrates a schematic fragmentary sectional view illustrating details of the behavior of the incident light and the output light in the display device of embodiment 1. In the display device of embodiment 1, it is assumed that the light is incident on the light output surface 30A of the laminated structure 30 at an incident angle θ₁ᵢ with respect to the light output surface 30A. Additionally, a refractive index of the adjacent layer 32 is assumed to be n₁. A refracting angle θ1r at a time when the light with the incident angle θ₁ᵢ intrudes into the adjacent layer 32 is expressed by following expression (1).

sin(θ₁ᵢ)=n₁·sin(θ₁ᵣ) (1)

Light that propagates in the adjacent layer 32 collides with a slope of the recessed and projected section 52, is reflected by the slope, and propagates toward the light output surface 30A. Here, it is assumed that the recessed and projected section 52 includes the square pyramid having the maximum inclination of α (degrees), and thus, an angle (refracting angle θ₂ᵣ) the light propagating toward the light output surface 30A makes with a normal to an interface between the adjacent layer 32 and the second protective layer 33 is as defined in following expression (2).

θ₂ᵣ=θ₁ᵣ+2α (2)

Further, a relationship between an angle θ₂ᵢ the light outputted from the light output surface 30A makes with a normal to the light output surface 30A and θ₂ᵣ is as defined in following expression (3).

sin(θ₂ᵢ)=n₁·sin(θ₂ᵣ) (3)

Substitution of expression (2) into expression (3) results in

$$\begin{matrix}sin ( {θ}_{2 i} ) = {n}_{1} \cdot sin \{ {θ}_{1 r} + 2 α \} \\ = {n}_{1} [ sin ( {θ}_{1 r} ) \cdot cos ( 2 α ) + cos ( {θ}_{1 r} ) \cdot sin ( 2 α ) ]\end{matrix} \qquad ( 4 )$$

Besides,

sin²(θ₁ᵣ)+cos²(θ₁ᵣ)=1

results in

cos(2θ₁ᵣ)={1−sin²(2θ₁ᵣ)}^{1/2}

and substitution of this into expression (4) results in

sin(θ₂ᵢ)=n₁[sin(θ₁ᵣ)·cos(2α)+{1−sin²(θ₁ᵣ)}^{1/2}·sin(2α)] (5)

Further, substitution of expression (1) into expression (5) results in

sin(θ₂ᵢ)=cos(2α)·sin(θ₁ᵢ)+sin(2α){n²−sin²(θ₁ᵢ)}^{1/2} (6)

Therefore,

θ₂ᵢ=sin⁻¹[cos(2α)·sin(θ₁ᵢ)+sin(2α){n²−sin²(θ₁ᵢ)}^{1/2}] (7) holds.

In a case where the light is incident on the light output surface 30A of the laminated structure 30 at the incident angle of θ₁ᵢ=0 (degrees) in the display device of embodiment 1, meanwhile, expression (6) may be presented as follows.

sin(621)=n₁·sin(2α) (8)

In a case where the light that is reflected by the slope of the recessed and projected section 52 and that propagates toward the light output surface 30A is then totally reflected by the light output surface 30A, the totally reflected light is returned to and collides afresh with the recessed and projected section forming layer 51, resultantly causes stray light, and may cause lowering of outside light contrast.

Here, sin(θ₂ᵢ) on left-hand side of expression (8) having a value of 1 makes a condition of the total reflection by the light output surface 30A of the light that propagates toward the light output surface 30A. In a case where the maximum inclination α (degrees) of the recessed and projected section 52 satisfies

n₁·sin(2α)<1 (9),

therefore, the light propagating toward the light output surface 30A of the laminated structure 30 is outputted from the light output surface 30A to the outside without being totally reflected by the light output surface 30A. Thus, occurrence of the stray light and the lowering of the outside light contrast may be reduced. On condition that expression (9) is satisfied even if a value of the incident angle θ₁ᵢ exceeds 0 degrees, the light that propagates toward the light output surface 30A of the laminated structure 30 is outputted from the light output surface 30A to the outside without being totally reflected by the light output surface 30A. Here, expression (9) is equivalent to a condition of occurrence of the total reflection in a state in which a critical angle of material constituting the adjacent layer to air is θ_{c}. Therefore, satisfaction of 0<α≤θ_{c}/2 causes output of light from the light output surface 30A to the outside without total reflection by the light output surface 30A.

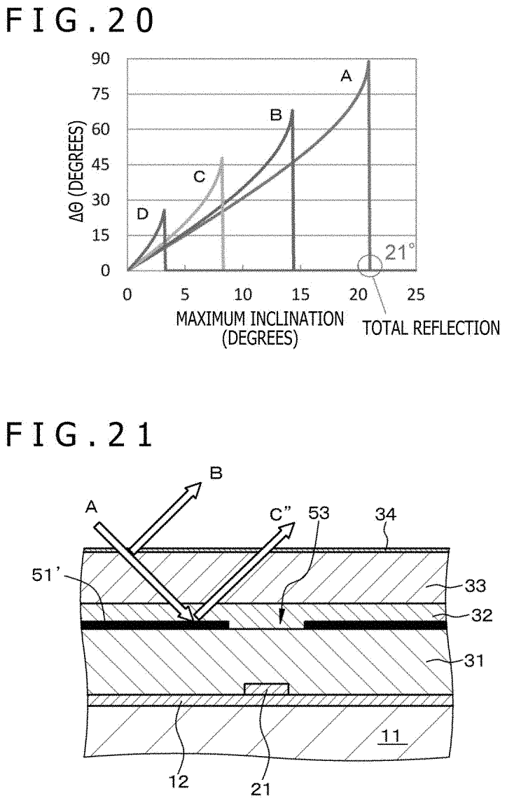

FIG. 20 illustrates results of calculation of relationships between the maximum inclination (α) and Δθ{=θ₂ᵢ−θ₁ᵢ] in a case of n₁=1.50. In FIG. 20, incidentally, “A” denotes data resulting from the incident angle θ₁ᵢ=0, “B” denotes data resulting from the incident angle θ₁ᵢ=20 degrees, “C” denotes data resulting from the incident angle θ₁ᵢ=40 degrees, and “D” denotes data resulting from the incident angle θ₁ᵢ=60 degrees. With setting of the value of the maximum inclination α to be equal to or smaller than 21 degrees, the light that propagates toward the light output surface 30A of the laminated structure 30 is outputted from the light output surface 30A to the outside without being totally reflected by the light output surface 30A. That is, the occurrence of the stray light and the lowering of the outside light contrast may be reduced.

As described above, it is desirable to satisfy 0<α≤θ_{c}/2 in which θ_{c} is the critical angle to air of the material constituting the layer (adjacent layer 32) that adjoins, on the light output side, the layer (recessed and projected section forming layer 51) on which the plural recessed and projected sections 52 are formed and in which a is the maximum inclination of the slope of each of the recessed and projected sections 52. As the value of the maximum inclination α, additionally, a value between one degree and two degrees may be presented. The outside light incident from the light output surface 30A of the laminated structure 30, except a portion absorbed by the laminated structure 30 and the recessed and projected section forming layer 51, is reflected by the layer (recessed and projected section forming layer 51) on which the plural recessed and projected sections 52 are formed and is outputted from the light output surface 30A of the laminated structure 30.

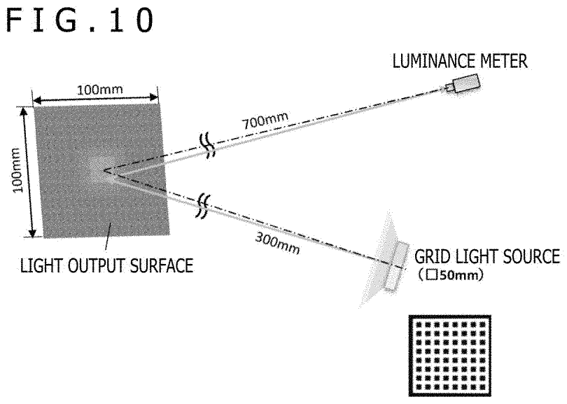

Simulations for evaluation of the image clarity of reflection and the outside light contrast were conducted. In the simulations, a system illustrated in FIG. 10 was assumed. That is, it was assumed that Lambertian light was outputted from a 50 mm×50 mm grid light source (Lambertian light source) toward the light output surface 30A that was 300 mm distant therefrom and that a surface state of the light output surface 30A where reflection of the grid light source occurred was measured by a luminance meter positioned at a distance of 700 mm from the light output surface 30A. In the display device of embodiment 1, additionally, the planar shapes of the recessed and projected sections 52 formed plural dots (each having a circular planar shape) regularly arrayed and each having a diameter of 50 μm, as illustrated in FIG. 2A, each of the plural recessed and projected sections 52 was placed on a vertex of a rectangle, and a placement pitch was 50 μm. It is desirable for a size of the recessed and projected sections 52 and the placement pitch of the recessed and projected section 52 to be sufficiently larger than a wavelength (λ₀) of the light outputted from the light output sections 21, for instance, to be equal to or larger than 1×10²·λ₀. It is additionally desirable for a placement density of the plural recessed and projected sections 52 to be as high as possible.

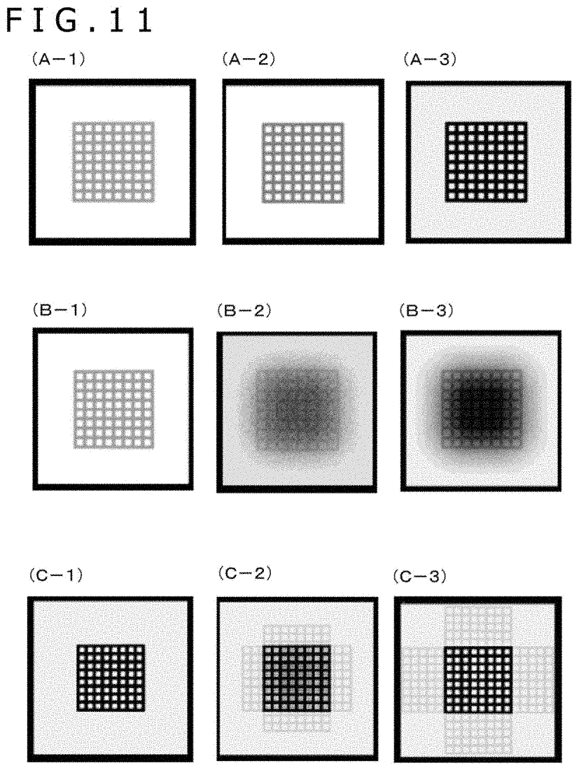

On the basis of the simulations in the conventional display device illustrated in FIG. 21 and including the black matrix layer 51″, (A-1) of FIG. 11 illustrates an image obtained from the light (see the light ray B in FIG. 21) reflected by the light output surface 30A of the laminated structure 30, (A-2) of FIG. 11 illustrates an image obtained from the light (see the light ray C″ in FIG. 21) reflected by the black matrix layer 51″, and (A-3) of FIG. 11 illustrates an image resulting from composition of the image illustrated in (A-1) of FIG. 11 and the image illustrated in (A-2) of FIG. 11. On the basis of the simulations in the display device of embodiment 1, similarly, (B-1) of FIG. 11 illustrates an image obtained from the light (see the light ray B in FIG. 1B) reflected by the light output surface 30A of the laminated structure 30, (B-2) of FIG. 11 illustrates an image obtained from the light (see the light ray C in FIG. 1B) reflected by the recessed and projected section forming layer 51, and (B-3) of FIG. 11 illustrates an image resulting from composition of the image illustrated in (B-1) of FIG. 11 and the image illustrated in (B-2) of FIG. 11. In the display device of embodiment 1, compared with (A-3) of FIG. 11, the definiteness and the clarity of an image of the grid light source are lowered as illustrated in (B-3) of FIG. 11. That is, the image clarity of reflection is reduced in the display device of embodiment 1 including the recessed and projected section forming layer 51, in comparison with the conventional display device.

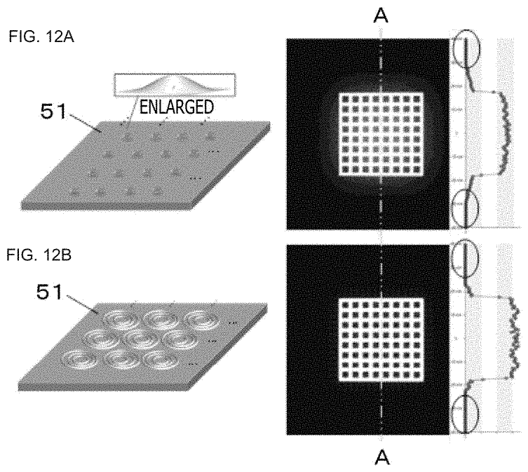

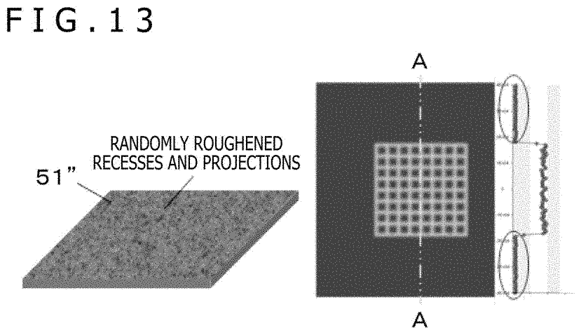

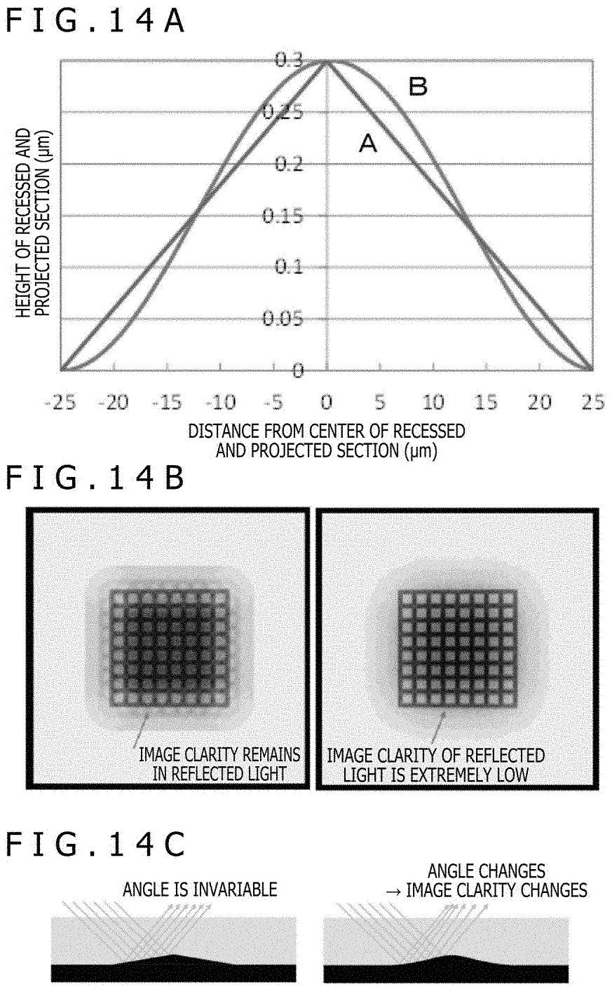

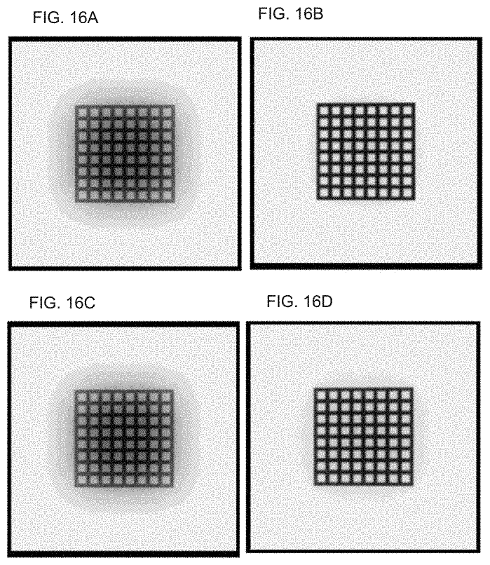

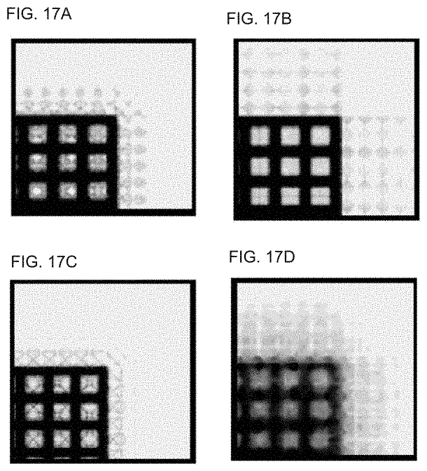

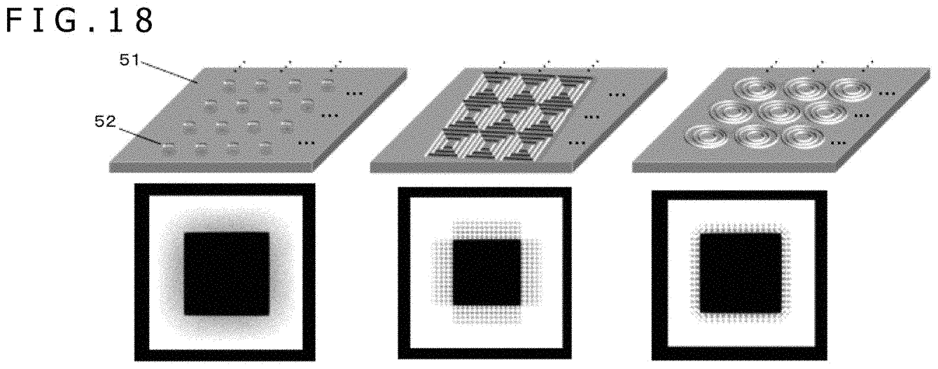

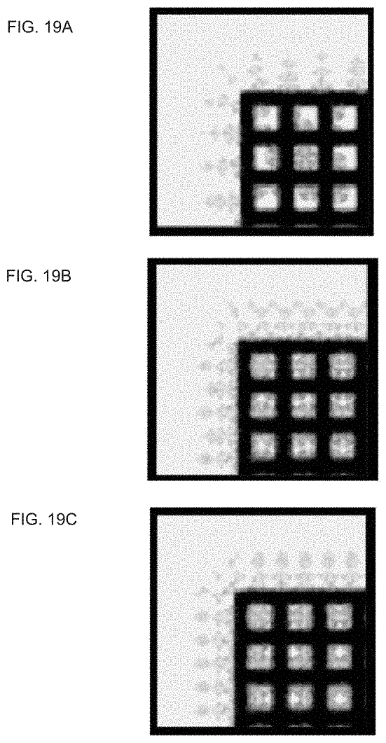

In FIG. 11 and FIG. 12, FIG. 13, FIG. 14B, FIG. 16, FIG. 17, FIG. 18, and FIG. 19 that will be described later, incidentally, images obtained on the basis of the light reflected by the light output surface 30A of the laminated structure 30 are illustrated in an opposite way. That is, bright portions of the images are illustrated as black portions in the drawings and dark portions of the images are illustrated as white portions in the drawings.

FIG. 13 illustrates a schematic perspective view of the black matrix layer in the conventional display device having a surface of the black matrix layer 51″ randomly roughened by sandblasting and a result of measurement of luminance of an image of the grid light source and that of an image of a region (referred to as an “outside region,” for convenience) positioned outside and in a vicinity of the image of the grid light source. The luminance of the outside region is not “zero.” Assuming that an average luminance of the image of the grid light source was 100, the average luminance of the outside region was “4.” In FIG. 12 and FIG. 13, the average luminance is illustrated with normalization. By contrast, (A) of FIG. 12 illustrates a schematic perspective view of the recessed and projected section forming layer in the display device of embodiment 1 and a result of measurement of luminance of an image of the grid light source and that of an image of a region (outside region) positioned outside and in a vicinity of the image of the grid light source, and (B) of FIG. 12 illustrates a schematic perspective view of the recessed and projected section forming layer in modification −1 to embodiment 1 that will be described later and a result of measurement of luminance of an image of the grid light source and that of an image of a region (outside region) positioned outside and in a vicinity of the image of the grid light source, the luminance of the outside region being “zero” in both cases. That is, it is observed that excellent outside light contrast may be obtained in the display device of embodiment 1 including the recessed and projected section forming layer 51 provided with the regular recessed and projected sections 52, in comparison with the conventional display device in which the light that collides with the black matrix layer 51″ is scattered and reflected in all directions by the randomly roughened surface of the black matrix layer 51″. Meanwhile, the measurement of the luminance was carried out along regions illustrated by A-A in FIG. 12 and A-A in FIG. 13.

In FIG. 11, (C-2) and (C-3) illustrate results of simulations as to how the image of the grid light source is viewed in the display device of embodiment 1 in which the maximum inclination α is set at one degree and at two degrees, and (C-1) illustrates a result of a simulation as to how the image of the grid light source is viewed in the conventional display device including the flat black matrix layer 51″. In the conventional display device including the flat black matrix layer 51″, the image obtained from the light ray B and the image obtained from the light ray C″ are viewed coincidently, as described before. In the display device of embodiment 1, by contrast, it is found that the image obtained from the light ray B and the image obtained from the light ray C are not viewed coincidently but are viewed as double images and that the image of the grid light source formed on the basis of the light ray C illustrated in FIG. 1B is expanded as the value of the maximum inclination increases.

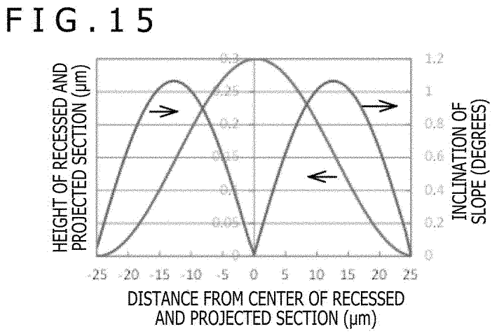

In the display device of embodiment 1, as described above, the planar shapes of the recessed and projected sections 52 were formed as the plural dots (each having the circular planar shape) regularly arrayed and each having the diameter of 50 μm, each of the plural recessed and projected sections 52 was placed on a vertex of a rectangle, and the placement pitch was 50 μm. Then, the image clarity of reflection in a case where the cross section of the slope cut by the virtual plane including the axis of the recessed and projected section 52 was a linear slope (see a graph A illustrating a sectional view in FIG. 14A) and in a case where the cross section was a curve (see a graph B illustrating a sectional view in FIG. 14A and see FIG. 15) was evaluated on the basis of the simulations. FIG. 14B illustrates results thereof, and it is found that the image clarity of reflection is further reduced in the case where the cross section of the slope cut by the virtual plane including the axis of the recessed and projected section 52 is the curve (see a graph at right in FIG. 14B), compared with the case where the cross section is the linear slope (see a graph at left in FIG. 14B). As FIG. 14C schematically illustrates behavior of light reflected by the slope of each of the recessed and projected sections 52 that has a linear section and the slope that has a curved section in the display device of embodiment 1, causally, light rays that collide with and are reflected by the recessed and projected section forming layer 51 are parallel in the case where the cross section of the slope cut by the virtual plane including the axis of the recessed and projected section 52 is linear (see a schematic diagram at left in FIG. 14C), whereas light rays that collide with and are reflected by the recessed and projected section forming layer 51 are not parallel in the case where the cross section of the slope cut by the virtual plane including the axis of the recessed and projected section 52 is curved (see a schematic diagram at right in FIG. 14C), so that the image clarity of reflection is further reduced.

In FIG. 16, (A) and (B) illustrate results of a simulation as to how much the image clarity of reflection is changed according to presence or absence of the antireflection membrane 34, and it is found that the image clarity of reflection is further reduced by provision of the antireflection membrane 34 (see (A) of FIG. 16), compared with the absence of the antireflection membrane 34 (see (B) of FIG. 16). That is, the provision of the antireflection membrane 34 generally causes further reduction in the image clarity of reflection because relative decrease in the proportion of the light ray B results in decrease in contribution of the image obtained from the light ray B to an entire image, while resulting in increase in contribution of the image obtained from the light ray C to the entire image. In addition, (C) and (D) of FIG. 16 illustrate results of a simulation as to how much the image clarity of reflection is changed between a case where each of the plural recessed and projected sections 52 is placed on a vertex of a rectangle and where the placement pitch is 50 μm and a case where each of the plural recessed and projected sections 52 is placed on a vertex of a rectangle and where the placement pitch is 100 μm, and it is found that the image clarity of reflection is further reduced in the case where the placement pitch is 50 μm (see (C) of FIG. 16), compared with the case where the placement pitch is 100 μm (see (D) of FIG. 16). That is, it is found that it is desirable for the placement density of the plural recessed and projected sections 52 to be as high as possible.

In the display device of embodiment 1, the light output surface of the laminated structure is flat, and the plural recessed and projected sections are formed on the interface of at least one layer positioned in the laminated structure. Therefore, outside light reflected by the light output surface of the laminated structure and outside light reflected by the layer (recessed and projected section forming layer) having the plural recessed and projected sections formed on the interface are made nonparallel to one another, so that the image clarity of reflection is reduced and the lowering of the outside light contrast is less likely to occur (that is, misadjusted black level is less likely to occur). Additionally, the light outputted from the light output sections may be prevented from being influenced by the recessed and projected section forming layer, and viewing angle characteristics may be prevented from deteriorating.

Though the planar shapes of the recessed and projected sections 52 are formed as the plural dots regularly arrayed in embodiment 1 described above, there is no limitation thereto. As FIG. 3A and FIG. 3B illustrate a schematic plan view and a schematic perspective view of modification −1 of the plural recessed and projected sections 52 in the display device of embodiment 1, the planar shape of each of the recessed and projected sections 52 may include a plurality of concentric circles. In FIG. 17, (A) illustrates part of a result of a simulation of the image clarity of reflection on the recessed and projected section forming layer 51 in which the recessed and projected sections 52 have such planar shapes. As FIG. 4 illustrates a schematic plan view of modification −2 of the plural recessed and projected sections 52 in the display device of embodiment 1, alternatively, the planar shape of each of the recessed and projected sections 52 may include a plurality of concentric rectangles. In FIG. 17, (B) illustrates part of a result of a simulation of the image clarity of reflection on the recessed and projected section forming layer 51 in which the recessed and projected sections 52 have such planar shapes. As FIG. 5 illustrates a schematic plan view of modification −3 of the plural recessed and projected sections 52 in the display device of embodiment 1, alternatively, the planar shape of each of the recessed and projected sections 52 may include a group of plural line segments extending radially. In FIG. 17, (C) illustrates part of a result of a simulation of the image clarity of reflection on the recessed and projected section forming layer 51 in which the recessed and projected sections 52 have such planar shapes. As FIG. 6 illustrates a schematic plan view of modification −4 of the plural recessed and projected sections 52 in the display device of embodiment 1, alternatively, the planar shape of each of the recessed and projected sections 52 may include a set of line segments that are line-asymmetric, point-asymmetric, and rotationally asymmetric (set of randomly placed line segments). In FIG. 17, (D) illustrates part of a result of a simulation of the image clarity of reflection on the recessed and projected section forming layer 51 in which the recessed and projected sections 52 have such planar shapes. Further, upper, middle, and lower tiers of FIG. 18 illustrate overall results of the simulations of the image clarity of reflection in the display devices of modification −1 and modification −2 to the display device of embodiment 1 and of embodiment 1. Meanwhile, the planar shape of each of the recessed and projected sections 52 may include a plurality of concentric polygons, and the planar shape of each of the recessed and projected sections 52 may include any combination of the planar shapes. The positional relationships between each of the plural recessed and projected sections 52 and the light output sections 21 are essentially optional. From (A), (B), (C), and (D) of FIG. 17, it is found that it is desirable to adopt modification −4 of the plural recessed and projected sections 52 in the display device of embodiment 1 in order to maximally reduce the image clarity of reflection.

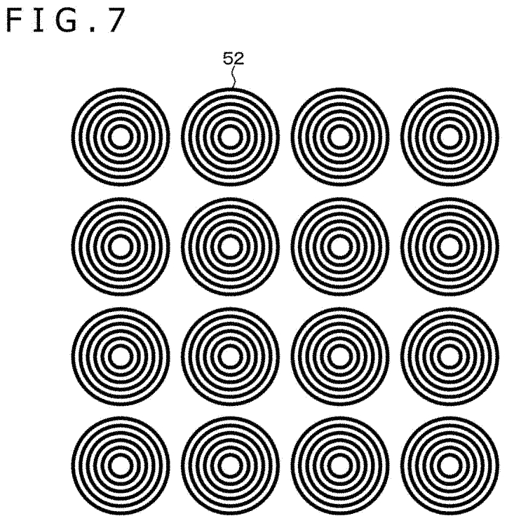

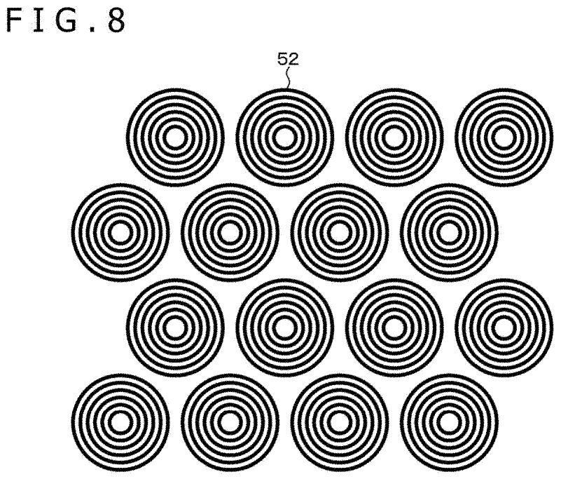

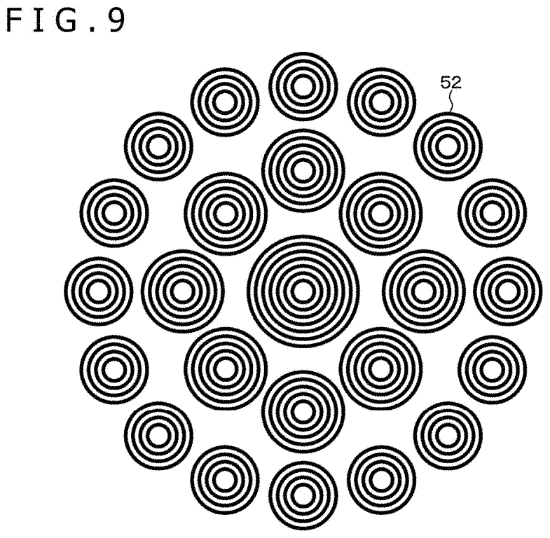

Additionally, though each of the plural recessed and projected sections 52 is placed on a vertex of a rectangle in embodiment 1 (see FIG. 2A or FIG. 7), each of the plural recessed and projected sections 52 may be placed on a vertex of a hexagon (see FIG. 8), may be placed radially (see FIG. 9), or may be placed randomly. The relationships between the placement position of each of the plural recessed and projected sections 52 and the placement positions of the light output sections 21 are essentially optional. In FIG. 19, (A), (B), and (C) illustrate part of results of simulations of the image clarity of reflection in a case where the plural recessed and projected sections 52 are placed on vertices of rectangles (see FIG. 7), in a case where the plural recessed and projected sections 52 are placed on vertices of hexagons (see FIG. 8), and in a case where the plural recessed and projected sections 52 are placed radially (see FIG. 9). The recessed and projected section forming layer 51 is illustrated by thick solid lines in FIG. 7, FIG. 8, and FIG. 9 and cross-sectional shapes of these recessed, and projected section forming layers 51 may be the same as the cross-sectional shape of the recessed and projected section 52 illustrated in FIG. 2B, for instance.

While display device of the present disclosure has been described above on the basis of the preferred embodiment, the display device of the present disclosure is not limited to this embodiment. Configurations and structures of the display device that have been described in relation to the embodiment are exemplary and may be modified appropriately, and the materials that have been described in relation to the embodiment and that constitute the display device are exemplary and may be modified appropriately. Plural recessed and projected section forming layers may be formed in the laminated structure, and a flat black matrix layer may be formed under the recessed and projected section forming layer (that is, between the recessed and projected section forming layer and the light output sections). The flat black matrix layer has a configuration and a structure that are the same as those of the recessed and projected section forming layer, except that the recessed and projected sections 52 are not formed.

In a case where the light output sections includes light emitting units, a fourth light emitting element, a fifth light emitting element, and so on may further be added to a first light emitting element, a second light emitting element, and a third light emitting element, as light emitting elements that constitute the light emitting unit. As such examples, a light emitting unit to which a sub pixel that emits white light is added for increase in luminance, a light emitting unit to which a sub pixel that emits light of a complementary color is added for expansion of a color reproduction range, a light emitting unit to which a sub pixel that emits yellow light is added for the expansion of the color reproduction range, and a light emitting unit to which sub pixels that emit yellow light and cyan light are added for the expansion of the color reproduction range may be presented, for instance.

Furthermore, the light output sections may each have a configuration including an electroluminescence element (EL element) or may each have a configuration including a liquid crystal display element. In these configurations, meanwhile, the laminated structure may have a configuration including the light passing region through which the light outputted from each light output section passes and the light non-passing region which is positioned outside the light passing region and which blocks the passage of the light outputted from the light output section or the laminated structure may have a structure in which layers including a material transparent to the light outputted from the light output sections are laminated, as a whole. In the latter case, the layer (recessed and projected section forming layer) on which the plural recessed and projected sections 52 are formed does not have to include a material that blocks passage of light. Here, in the configuration in which the light output sections include electroluminescence elements (EL elements) or liquid crystal display elements, the display device may include an electroluminescence display device or a liquid crystal display device.

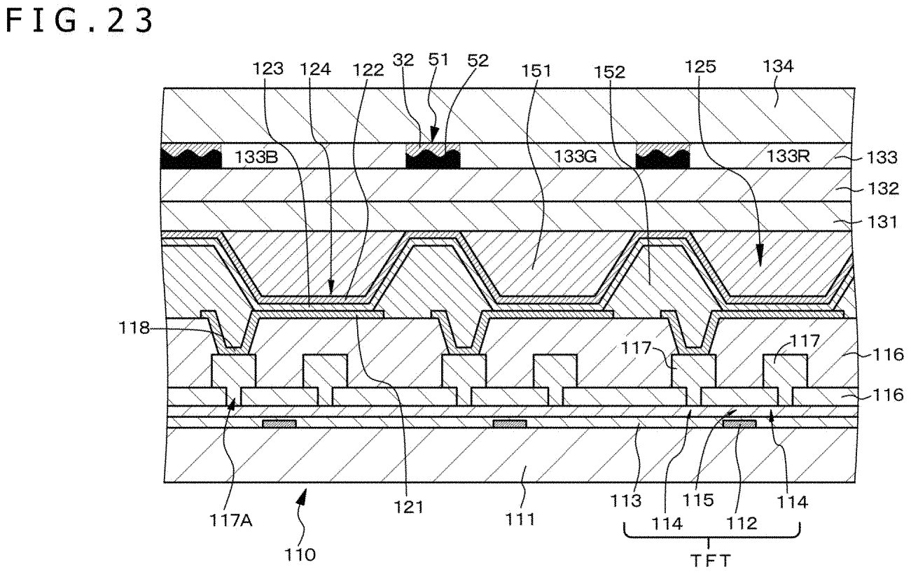

Specifically, the display device includes the electroluminescence display device (organic EL display device) as illustrated in a schematic fragmentary sectional view in FIG. 23. The organic EL display device includes the following:

(A) a first substrate 111 on which plural light emitting elements 110 each including a lamination of a first electrode 121, a light emitting section 124 including an organic layer 123 including a light emitting layer including an organic light emitting material, for instance, and a second electrode 122 are formed; and

(B) a second substrate 134 placed above the second electrode 122. More specifically, here, each organic EL element 110 includes the following:

(a) the first electrode 121;

(b) a second member 152 which has an opening 125 and in which the first electrode 121 is exposed at a bottom of the opening 125;

(c) the organic layer 123 which is provided at least on a portion of the first electrode 121 exposed at the bottom of the opening 125 and which includes the light emitting layer including the organic light emitting material, for instance; and

(d) the second electrode 122 formed on the organic layer 123. In addition, the first substrate 111 includes first members 151 that transmit light from each light emitting element 110 and that outputs the light to the outside. The second members 152 are filled into between the first members 151.

Therein, one pixel includes three sub pixels that are a red light emitting sub pixel which emits red light, a green light emitting sub pixel which emits green light, and a blue light emitting sub pixel which emits blue light. Further, the second substrate 134 includes color filters 133 (133R, 133G, and 133B), and the recessed and projected section forming layer 51 on which the plural recessed and projected sections 52 are formed is formed between the color filters 133. Additionally, a protective film 131 and a sealing material layer 132 are further provided above the first members 151 and the second electrodes 122. The color filters 133 and the recessed and projected section forming layer 51 are provided between the sealing material layer 132 and the second substrate 134. The adjacent layer 32 is formed between the recessed and projected section forming layer 51 and the second substrate 134. According to circumstances, meanwhile, formation of the color filters 133 may be omitted.

The first electrode 121 constituting the organic EL element is provided on an interlayer insulation layer 116. Further, the interlayer insulation layer 116 covers organic EL element drive sections formed on the first substrate 111. The organic EL element drive sections include a plurality of TFTs, and electrical connections between the TFTs and the first electrodes 121 are made through contact plugs 118, wiring 117, and contact plugs 117A that are provided in the interlayer insulation layer 116. Meanwhile, one TFT is illustrated corresponding to one organic EL element drive section in the drawing. The TFT includes a gate electrode 112 formed on the first substrate 111, a gate insulation membrane 113 formed on the first substrate 111 and the gate electrode 112, a source/drain region 114 provided in a semiconductor layer formed on the gate insulation membrane 113, and a channel forming region 115 to which a portion of the semiconductor layer positioned between the source/drain regions 114 and above the gate electrode 112 corresponds. Though the TFTs are of a bottom gate type in an illustrated example, meanwhile, the TFTs may be of a top gate type. The gate electrodes 112 of the TFTs are connected to a scanning circuit (not illustrated).

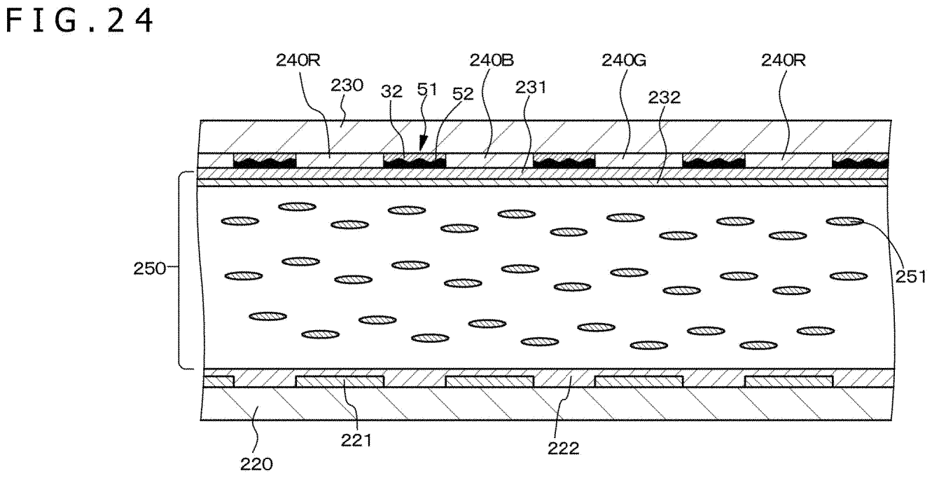

As FIG. 24 illustrates a schematic fragmentary sectional view, otherwise, a liquid crystal display device includes plural pixels. Further, the liquid crystal display device includes a TFT (Thin Film Transistor) substrate 220 and a CF (Color Filter) substrate 230. More specifically, the liquid crystal display device includes plural arrayed pixels each including the following:

the first substrate (TFT substrate) 220 and the second substrate (CF substrate) 230;

a first electrode (pixel electrode) 221 formed on a facing surface of the first substrate 220 facing the second substrate 230;

a first oriented film 222 covering the first electrode (pixel electrode) 221 and the facing surface of the first substrate (TFT substrate) 220;

a second electrode (facing electrode) 231 formed on a facing surface of the second substrate (CF substrate) 230 facing the first substrate (TFT substrate) 220;

a second oriented film 232 covering the second electrode (facing electrode) 231 and the facing surface of the second substrate (CF substrate) 230; and

a liquid crystal layer 250 provided between the first oriented film 222 and the second oriented film 232 and including liquid crystal molecules 251.

Further, the first substrate 220 is provided with TFT switching elements including gates, sources, drains, and the like that drive each of the pixel electrodes 221, gate wires, source wires, and the like that are connected to the TFT switching elements (not illustrated), and the like, whereas illustration thereof is omitted. On the CF substrate 230, color filters 240 (240R, 240G, and 240B) including stripe filters of red (R), green (G), and blue (B), for instance, are provided on a surface facing the TFT substrate 220, across substantially the whole surface in an effective display region, and between a facing electrode 231 and the second substrate 230. The recessed and projected section forming layer 51 on which the plural recessed and projected sections 52 are formed is formed between the color filters 240. The adjacent layer 32 is formed between the recessed and projected section forming layer 51 and the second substrate 230.

The display device (light emitting element display device) may be used not only as a color image display device of a flat type or a direct view type typified by a television receiver, a computer terminal, and the like but also as an image display device of a type that projects an image onto a human retina or an image display device of a projection type. For these image display devices, meanwhile, it is sufficient if a field sequential driving scheme in which an image is displayed with time sharing control over light-emitting/no-light-emitting state of each of the first light emitting element, the second light emitting element, and the third light emitting element, for instance, is adopted, though there is no limitation thereto.

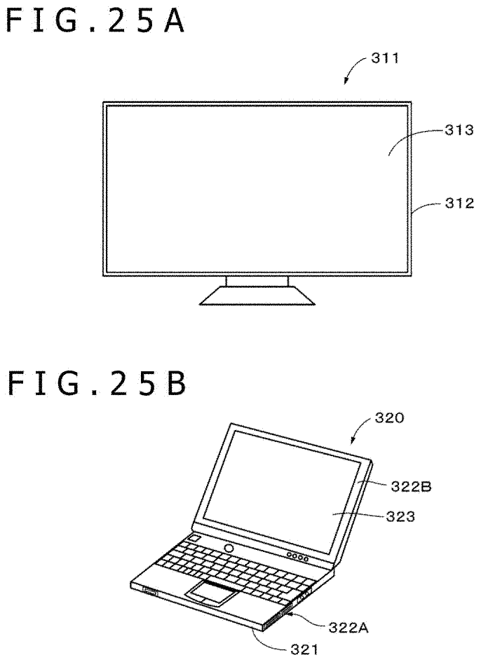

FIG. 25A is an exterior diagram illustrating an example of a television receiver as the display device. The television receiver 311 includes an enclosure 312 and a display device 313 housed in the enclosure 312. Here, it is sufficient if the display device 313 includes the display device of embodiment 1 that has been described above or the organic EL display device, the liquid crystal display device, or the like that has been described above. FIG. 25B is an exterior diagram illustrating a display device of a notebook personal computer, as the display device. A notebook personal computer 320 includes a computer main unit 321 and a display device 323. The computer main unit 321 and the display device 323 are respectively housed in an enclosure 322A and an enclosure 322B. Here, it is sufficient if the display device 323 includes the display device of embodiment 1 that has been described above or the organic EL display device, the liquid crystal display device, or the like that has been described above.

Meanwhile, the present disclosure may also have such a configuration as follows.

### [A01]

### <<Display Device>>

A display device including a plurality of arrayed light output sections covered with a laminated structure, in which the laminated structure includes a plurality of laminated layers, and a light output surface is flat, and plural recessed and projected sections are formed on an interface of at least one layer positioned in the laminated structure.

### [A02]

The display device according to [A01], in which the laminated structure includes a light passing region through which light outputted from each of the light output sections passes and a light non-passing region which is positioned outside the light passing region and which blocks passage of the light outputted from the light output section, and

the at least one layer positioned in the laminated structure is positioned in the light non-passing region, and a recessed and projected section is formed on an interface on a light output side of the at least one layer positioned in the laminated structure.

### [A03]

The display device according to [A02], in which the layer on which the plural recessed and projected sections are formed includes a material that blocks passage of light.

### [A04]

The display device according to any one of [A01] through [A03], in which

0<α≤θ_{c}/2 is satisfied in which θ_{c} is a critical angle to air of a material constituting a layer that adjoins, on the light output side, the layer on which the plural recessed and projected sections are formed and a is a maximum inclination of a slope of each of the recessed and projected sections.

### [A05]

The display device according to [A04], in which a value of a is between one degree and two degrees.

### [A06]

The display device according to either one of [A04] and [A05], in which

a cross-section of a slope cut by a virtual plane including an axis of each of the recessed and projected sections includes a curve.

### [A07]

The display device according to any one of [A01] through [A06], in which

an antireflection membrane is formed on the light output surface of the laminated structure.

### [A08]

The display device according to any one of [A01] through [A07], in which

a planar shape of each of the recessed and projected sections includes at least one type of shape selected from a group including a plurality of concentric circles, a plurality of concentric rectangles, a plurality of concentric polygons, a set of a plurality of line segments extending radially, a plurality of dots regularly arrayed, and a set of line segments that are line-asymmetric, point-asymmetric, and rotationally asymmetric.

### [A09]

The display device according to any one of [A01] through [A08], in which

each of the plural recessed and projected sections is placed on a vertex of a rectangle, on a vertex of a hexagon, or radially.

### [A10]

The display device according to any one of [A01] through [A09], in which

outside light incident from the light output surface of the laminated structure is reflected by the layer on which the plural recessed and projected sections are formed and is outputted from the light output surface of the laminated structure.

### [A11]

The display device according to any one of [A01] through [A10], in which

the light output sections include light emitting diodes.

### [A12]

The display device according to any one of [A01] through [A10], in which

the light output sections include semiconductor laser elements.

### [A13]

The display device according to any one of [A01] through [A10], in which

the light output sections include electroluminescence elements.

### [A14]

The display device according to any one of [A01] through [A10], in which

the light output sections include liquid crystal display elements.

### REFERENCE SIGNS LIST

11 . . . Base, 12 . . . Wiring layer, 21 . . . Light output section, 30 . . . Laminated structure, 30A . . . Light output surface, 30B . . . Light passing region, 30C . . . Light non-passing region, 31 . . . Resin layer (protective layer), 32 . . . Adjacent layer, 33 . . . Second protective layer, 34 . . . Antireflection membrane, 51 . . . Recessed and projected section forming layer, 51″ . . . Black matrix layer, 52 . . . Recessed and projected section, 110 . . . Light emitting element (organic EL element), 111 . . . First substrate, 112 . . . Gate electrode, 113 . . . Gate insulation film, 114 . . . Source/drain region, 115 . . . Channel forming region, 1116 . . . Interlayer insulation layer, 117A, 118 . . . Contact plug, 117 . . . Wiring, 121 . . . First electrode, 122 . . . Second electrode, 123 . . . Organic layer, 124 . . . Light emitting section, 134 . . . Second substrate, 125 . . . Opening section, 151 . . . First member, 152 . . . Second member, 131 . . . Protective film, 132 . . . Sealing material layer, 133, 133R, 133G, 133B . . . Color filter, 220 . . . TFT (Thin Film Transistor) substrate, 221 . . . First electrode (pixel electrode), 222 . . . First oriented film 222, 230 . . . CF (Color Filter) substrate, 231 . . . Second electrode (facing electrode), 232 . . . Second oriented film, 240, 240R, 240G, 240B . . . Color filter, 250 . . . Liquid crystal layer, 251 . . . Liquid crystal molecule

1. A display device including a plurality of arrayed light output sections covered with a laminated structure, wherein
the laminated structure includes a plurality of laminated layers, and a light output surface is flat, and
plural recessed and projected sections are formed on an interface of at least one layer positioned in the laminated structure.

2. The display device according to claim 1, wherein
the laminated structure includes a light passing region through which light outputted from each of the light output sections passes and a light non-passing region which is positioned outside the light passing region and which blocks passage of the light outputted from the light output section, and
the at least one layer positioned in the laminated structure is positioned in the light non-passing region, and a recessed and projected section is formed on an interface on a light output side of the at least one layer positioned in the laminated structure.

3. The display device according to claim 2, wherein
the layer on which the plural recessed and projected section are formed includes a material that blocks passage of light.

4. The display device according to claim 1, wherein
0<α≤θ_{c}/2 is satisfied in which θ_{c} is a critical angle to air of a material constituting a layer that adjoins, on a light output side, the layer on which the plural recessed and projected sections are formed and a is a maximum inclination of a slope of each of the recessed and projected sections.

5. The display device according to claim 4, wherein
a value of a is between one degree and two degrees.

6. The display device according to claim 4, wherein
a cross-section of a slope cut by a virtual plane including an axis of each of the recessed and projected sections includes a curve.

7. The display device according to claim 1, wherein
an antireflection membrane is formed on the light output surface of the laminated structure.

8. The display device according to claim 1, wherein
a planar shape of each of the recessed and projected sections includes at least one type of shape selected from a group including a plurality of concentric circles, a plurality of concentric rectangles, a plurality of concentric polygons, a set of a plurality of line segments extending radially, a plurality of dots regularly arrayed, and a set of line segments that are line-asymmetric, point-asymmetric, and rotationally asymmetric.

9. The display device according to claim 1, wherein
each of the plural recessed and projected sections is placed on a vertex of a rectangle, on a vertex of a hexagon, or radially.

10. The display device according to claim 1, wherein
outside light incident from the light output surface of the laminated structure is reflected by the layer on which the plural recessed and projected sections are formed and is outputted from the light output surface of the laminated structure.

11. The display device according to claim 1, wherein
the light output sections include light emitting diodes.

12. The display device according to claim 1, wherein
the light output sections include semiconductor laser elements.

13. The display device according to claim 1, wherein
the light output sections include electroluminescence elements.

14. The display device according to claim 1, wherein
the light output sections include liquid crystal display elements.
